(19) United States
(12) Patent Application Publication
(10) Pub. No.: US 2018/0351577 A1
(43) Pub. Date: Dec. 6, 2018

(54) ITERATION-ADAPTIVE DECODING FOR NON-BINARY LDPC CODES

(71) Applicant: Western Digital Technologies, Inc., San Jose, CA (US)

(72) Inventors: Minghai QIN, San Jose, CA (US); Zvonimir Z. BANDIC, San Jose, CA (US); Dejan VUCINIC, San Jose, CA (US)

(21) Appl. No.: 15/608,174

(22) Filed: May 30, 2017

(51) Int. Cl. H03M 13/11; H03M 13/29

(52) U.S. Cl. CPC H03M 13/1171; H03M 13/1125; H03M 13/2948

(57) ABSTRACT

Embodiments of a data storage device include a non-volatile memory and a controller coupled to the non-volatile memory. The controller includes a decoder configured to decode a non-binary code, such as a low-density parity-check (LDPC) code. The decoder decodes the code by generating variable-node-to-check-node message vectors and by generating check-node-to-variable-node message vectors. When generating variable-node-to-check-node message vectors, the decoder considering a first number and then a second greater number of components of the variable-node-to-check-node message vectors. Embodiments of a method of decoding non-binary codes, such as non-binary LDPC codes, include generating variable node message vectors and check node message vectors in logarithm form. The check node message vectors are generated at a first complexity less than a full complexity of considering all components of the variable node message vectors and generated at a second complexity greater than the first complexity.

### BACKGROUND OF THE DISCLOSURE

### Field of the Disclosure

This disclosure relates to data storage devices. More particularly, the disclosure relates to a non-binary decoder operable to decode data storage in a data storage device.

### Description of the Related Art

Non-volatile memory arrays often have limited endurance. The endurance of the memory array is typically contingent on usage pattern and wear. In addition, the endurance depends on a type of the non-volatile memory array used. Memory arrays with multi-level cell (MLC) NAND media typically have a lower endurance than memory arrays with single-level cell (SLC) NAND media. To protect user data stored to memory arrays from corruption, which may be caused by a diminished endurance, user data can be encoded by generating parity data that can be stored along with user data to facilitate error detection and correction. However, decoding of encoded data can be time consuming and resource intensive. Accordingly, it is desirable to provide an improved decoder and method of decoding data.

### SUMMARY OF THE DISCLOSURE

The disclosure relates to a non-binary decoder operable to decode data storage in a data storage device. Embodiments of a data storage device include a non-volatile memory and a controller coupled to the non-volatile memory. The controller includes a decoder configured to decode a non-binary code, such as a low-density parity-check (LDPC) code. The decoder decodes the code by generating variable-node-to-check-node message vectors and by generating check-node-to-variable-node message vectors. When generating variable-node-to-check-node message vectors, the decoder considers a first number and then a second greater number of components of the variable-node-to-check-node message vectors. Other embodiments of a data storage device include a controller comprising a decoder means. The decoder means is operable to decode a portion of a codeword by performing a non-binary low-density parity-check (LDPC) decoding process by using a first number of largest log density ratio (LDR) values and by using a second number of largest LDR values in which the second number is greater than the first number.

Embodiments of a method of decoding non-binary codes, such as non-binary LDPC codes, include generating variable node message vectors and check node message vectors in logarithm form. The check node message vectors are generated at a first complexity less than a full complexity of considering all components of the variable node message vectors and generated at a second complexity greater than the first complexity.

Embodiments of a non-transitory computer readable storage medium containing instructions that, when executed by a controller, perform a method for decoding codewords in a data storage device. The method includes determining a plurality of variable-node-to-check-node message vectors, considering a first set of largest magnitude components of the variable-node-to-check-node message vectors for one or more iterations, and considering a second set of largest magnitude components of the of the variable-node-to-check-node message vectors for one or more additional iterations. The second set of components is larger in size than the first set of components.

### BRIEF DESCRIPTION OF THE DRAWINGS

FIG. 1 is a schematic diagram of one embodiment of a data storage device that implements a non-binary decoder.

FIG. 2 is a schematic diagram of one embodiment of a decoder of a controller of a data storage device.

FIG. 3 is a flowchart illustrating one embodiment of a process of decoding a codeword.

FIG. 4 is a flowchart illustrating another embodiment of a process of decoding a codeword.

FIG. 5 is a graph illustrating signal-to-noise ratios and frame error rates for simulation of one embodiment of a decoder performing decoding.

FIG. 6 is a graph illustrating signal-to-noise ratios and frame error rates for simulation of another embodiment of a decoder performing decoding.

FIG. 7 is a graph illustrating signal-to-noise ratios and number of iterations for simulation of another embodiment of a decoder performing decoding.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following, reference is made to embodiments of the disclosure. However, it should be understood that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in the claim(s).

Data storage devices, such as solid state drives or hard disk drives, typically include one or more controllers coupled with one or more non-volatile memory (NVM) arrays. Stored data may be subject to corruption as a result of read/write disturbs, loss of data retention, loss of endurance, or other causes. Data storage devices may utilize one or more error correction or error coding mechanisms to detect and/or correct errors in the stored data. One such mechanism may determine parity data when writing data. Parity data may be stored, for example, in NVM. When stored data is retrieved, parity data may be utilized as part of a decoding process to determine the integrity of the retrieved data. If one or more errors are detected, such errors may be corrected.

One type of error correction or error coding mechanism that may be used by data storage devices to code data is low-density parity-check (LDPC) codes. To manage LDPC coding, the data storage devices may include a decoder and an encoder that utilize the LDPC codes for decoding and generating parity data, respectively. The decoding process performed by the decoder may involve an iterative decoding process where values (for example, probabilities or likelihoods of belief) are passed between variable nodes and check nodes to decode data. Data storage devices may implement LDPC coding to enable processing of binary LDPC codes or non-binary LDPC codes.

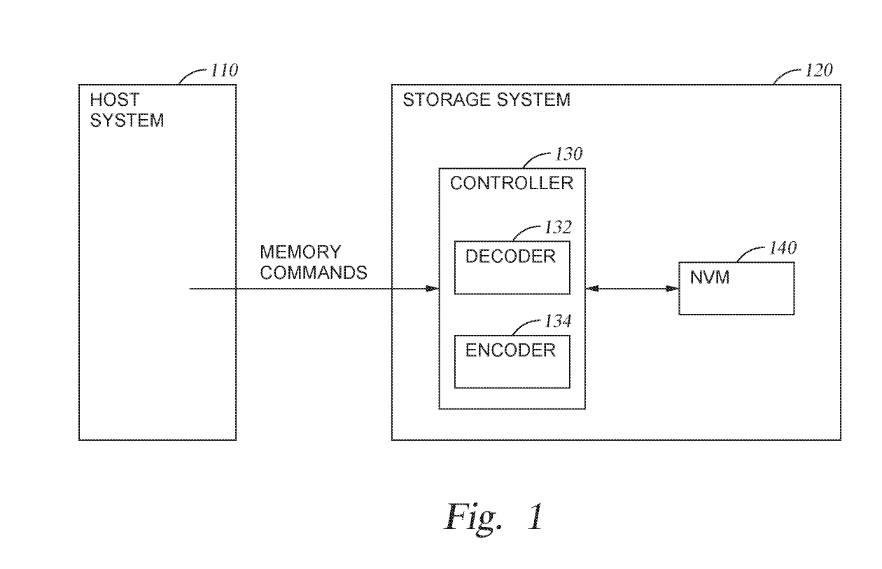

FIG. 1 is a schematic diagram of one embodiment of a data storage device 120 that implements a non-binary decoder, such as non-binary LDPC processing. The data storage device 120, such as a solid state drive (SSD), a hard disk drive, or a hybrid drive, includes non-volatile memory (NVM) 140 controlled by a controller 130.

NVM 140 may be configured for long-term storage of data and retain data after power on/off cycles. Examples of NVM include NAND memory (e.g., single-level cell (SLC) memory, multi-level cell (MLC) memory, triple level cell memory, X4 cell memory, etc.), NOR memory, phase change memories (PC-RAM or PRAM), resistive RAM (ReRAM) memories, magnetoresistive RAM (MRAM) memories, magnetic media (including shingle magnetic recording), optical disks, floppy disks, electrically programmable read only memories (EPROM), electrically erasable programmable read only memories (EEPROM), and other solid-state memories. Magnetic media non-volatile memory may be one or more magnetic platters. Each platter may contain one or more regions of one or more tracks of data. NVM 140 may include a single or a combination of one or more types of memories.

Host system 110 communicates with data storage device 120 to provide data storage commands to controller 130. Controller 130 may be configured to receive data storage access commands from host system 110, such as read, write, and erase data commands. Controller 130 executes the received commands to read, write, and erase data from NVM 140.

Controller 130 includes a decoder 132 and an encoder 134 configured to decode and encode data, respectively, stored in and retrieved from NVM 140. Encoder 134 may encode stored data to protect the data from potential errors during retrieval of stored data. Decoder 132 may perform error detection to determine the integrity of data retrieved from NVM 140 and perform, if necessary, error correction of retrieved data. In some embodiments, encoder 134 encodes stored data using non-binary LDPC codes and decoder 132 decodes non-binary LDPC coded data.

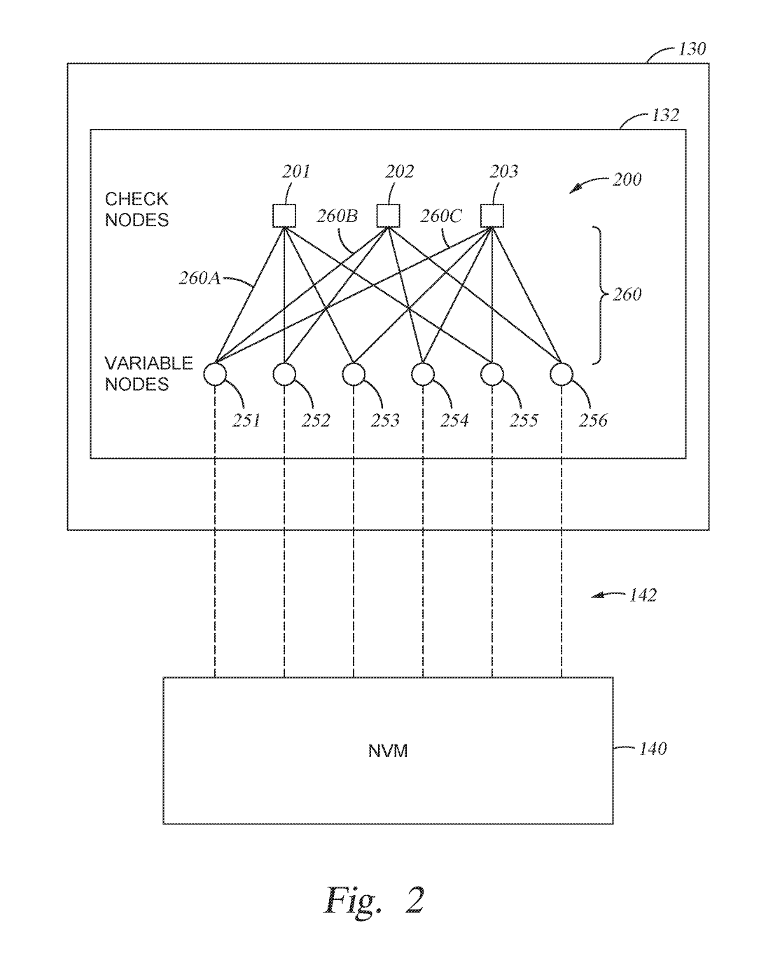

FIG. 2 is a schematic diagram of one embodiment of decoder 132 of controller 130 of FIG. 1. Decoder 132 may be a low density parity check code (LDPC) decoder for decoding one or more bits of a codeword on a channel 142 of NVM 140. The codewords on channel 142 may have been encoded by encoder 134, such as an LDPC encoder. Channel 142 may be any medium capable of storing and/or transmitting data.

Decoder 132 may be configured to divide the codeword among a plurality of variable nodes 251-256. In binary LDPC decoders, each variable node 251-256 contains a single bit to store a logical one or a logical zero. In non-binary LDPC decoders, each variable node 251-256 contains symbols representing a group of bits. In either binary LDPC decoders or non-binary LDPC decoders, the variable nodes 251-256 may be related or relatable to each other by a plurality of check nodes 201-203 or constraint nodes.

In decoding the codewords, messages are passed between variable nodes 251-256 and check nodes according to connections or edges 260. Each variable node 251-256 may include a confidence value for one or more bits of the codeword, the confidence value provides some indication as to whether these bits of the codeword are correct or valid. The number of variable nodes 251-256, check nodes 201-2013, and edges 260 are schematically represented by a tanner graph 200 as shown in the embodiment of FIG. 2. The number of variable nodes, check nodes, and edges may be determined based upon the strength and complexity of the decoder desired.

Messages are passed between connected variable nodes 251-256 and check nodes 201-203 in an iterative process in which beliefs about the values that should appear in variable nodes are passed back-and-forth. Parity checks are performed in the check nodes 201-203 based on the messages received from the variable nodes 251-256 and the results are returned to connected variable nodes 251-256 to update the beliefs, if necessary. By providing multiple check nodes 201-203 for the group of variable nodes 251-256, redundancy in error checking is provided enabling errors to be detected and corrected.

Each check node 201-203 performs a parity check on bits or symbols passed as messages from its connected variable nodes 251-256. In the example as shown in FIG. 2 corresponding to the Tanner graph 200, check node 201 checks the parity of variable nodes 251, 252, 253, 255; check node 202 checks the parity of variable nodes 251, 252, 254, 256; and check node 203 checks the parity of variable nodes 251, 253, 254, 255, 256.

Values are passed back and forth between variable nodes 251-256 and connected check nodes 201-203 along edges 260 in an iterative process until the LDPC code converges on a value for the group of data and parity bits in the variable nodes 251-256. For example, variable node 251 passes messages to check nodes 201, 202, 203. Check node 201 passes messages back to variable nodes 251, 252, 253, 255. The messages between variable nodes 251-256 and check nodes 201-203 are probabilities or beliefs. Each message from a check node represents the probability that a bit or symbol has a certain value based on the current value of the node and on previous messages to the node. Decoding iterations are performed by passing messages back and forth between variable nodes 251-256 and check nodes 201-203 with the values in the variable nodes 251-256 being adjusted based on the messages that are passed until the values converge and stop changing or until processing is halted. The values in variable nodes 251-256 may converge in a single iteration of messages being passed from variable nodes 251-256 to check nodes 201-203 or in multiple iterations.

LDPC decoders may be implemented in a binary fashion or a non-binary fashion. In a binary LDPC decoder, variable nodes 251-256 contain binary values on a group of data and parity bits that are retrieved from NVM 140 through channel 142. Messages in the binary LDPC decoders are values, such as log-likelihood-ratio (LLR) values and log density ratio (LDR) values, representing the probability that the sending variable node contains a value 0 or 1.

In a non-binary LDPC decoder, variable nodes 251-256 contain symbols on a group of data and parity bits that are retrieved from NVM 140 through channel 142. The symbols are defined from a Galois Field, a finite field GF(q) that contains a finite number of elements, characterized by size q or size 2^{m}. Messages in the non-binary LDPC decoders are multi-dimensional vectors, including LLR vectors and LDR vectors, indicating a probability of a symbol being 0, a probability of a symbol being 1,a probability of a symbol being α², a probability of a symbol being α³ to a probability of a symbol being α^{q-2}.

In certain embodiments of decoder 132 of FIG. 1 and FIG. 2 being a non-binary LDPC decoder, each variable nodes 251-256 may provide messages in vectors in the log domain or in logarithm form. For example, each variable nodes 251-256 may provide an initial LDR vector L^{(j)} made up of LDR components Lᵢ^{(j)} expressed as follows:

$${L}_{i}^{〈 j 〉} = log \frac{ {P}_{i}^{〈 j 〉}}{ {P}_{0}^{〈 j 〉}} \qquad ( 1 )$$

where Pᵢ^{(j)} represents the probability of j-th edge being symbol i ∈ {0, 1, α¹, . . . α^{q-2}}. The LDR vector L^{(j)} message may be expressed as follows:

L^{(j)}=[L₀^{(j)} . . . L_{q-1}^{(j)}] (2)

Each variable node 251-256 has incoming message from connected check nodes 201-203. By combining with input messages, each variable node sends output messages to its adjacent check nodes 201-203. For example, variable node 251 may receive messages from check nodes 202, 203 through edges 260B, 260C and may send an update to check node 201 through edge 260A. Variable node 251 sends update Pᵢ⁽¹⁾ to check node 201 which is proportional to messages Pᵢ⁽²⁾ from check node 202 multiplied by Pᵢ⁽³⁾ from check nodes 203. The variable node update in the log domain or logarithm form may be expressed as follows:

Lᵢ⁽¹⁾=Lᵢ⁽²⁾+Lᵢ⁽³⁾, ∀i ∈ {0, 1, a¹, . . . α^{q-2}}⇄{0, 1, 2, . . . q−1} (3)

For each check node 201-203, incoming messages from connected variables nodes 251-256 are considered. For example, check node 201 may consider incoming messages from variable nodes 252, 253, 255 and send an update to variable node 251. The check nodes LDR updates may be expressed in the log domain or logarithm form as follows:

$${L}_{i}^{i 〈 1 〉} = log \frac{ {P}_{i}^{〈 1 〉}}{ {P}_{0}^{〈 1 〉}} where {P}_{i}^{〈 1 〉} = {\sum }_{{x + y + z = i}_{x , y , z ∈ GF ( q )}} {P}_{x}^{〈 2 〉} {P}_{y}^{〈 3 〉} {P}_{z}^{〈 4 〉} \qquad ( 4 )$$

which may be approximated using an extended min sum (EMS) calculation as follows:

$${L}_{i}^{i 〈 1 〉} \approx {max}_{{x + y + z = i}_{x , y , z ∈ GF ( q )}} ( {L}_{x}^{〈 2 〉} + {L}_{y}^{〈 3 〉} + {L}_{z}^{〈 4 〉} ) - {min}_{{x + y + z = 0}_{x , y , z ∈ GF ( q )}} ( {L}_{x}^{〈 2 〉} + {L}_{y}^{〈 3 〉} + {L}_{z}^{〈 4 〉} ) \qquad ( 5 )$$

The above equations are examples, and other equations incorporating other non-binary decoding using different permutations and/or different convolutions may be used.

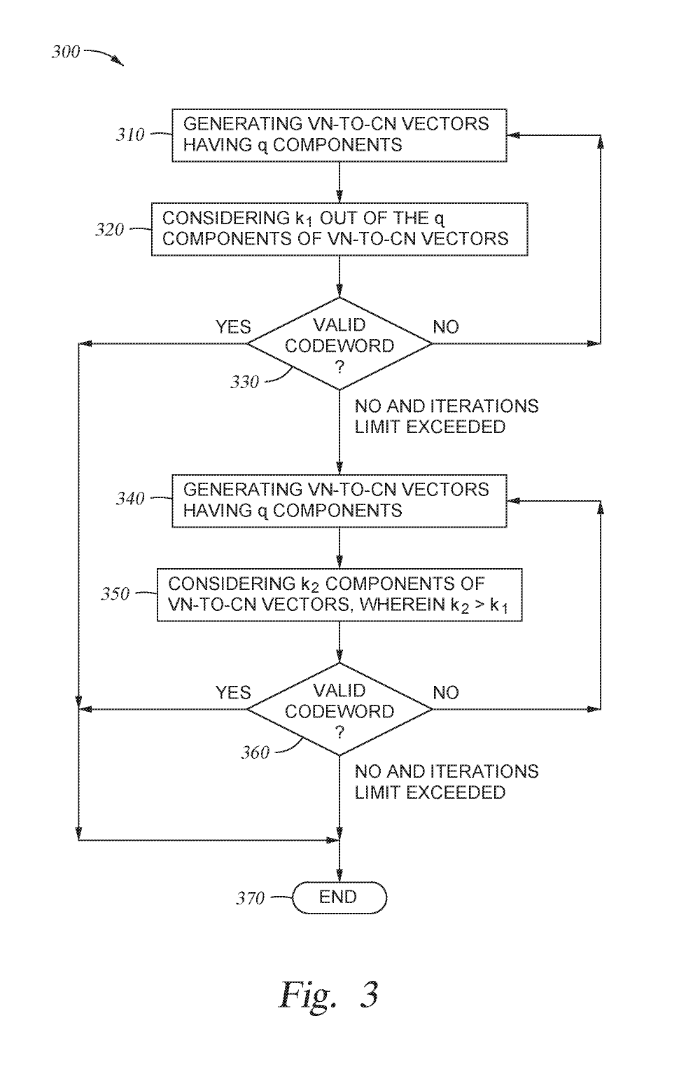

FIG. 3 is a flowchart 300 illustrating one embodiment of a process of decoding a codeword (or portion of a codeword) performed by a non-binary LDPC decoder. Flowchart 300 is described in reference to decoder 132 of FIG. 1 and FIG. 2. The process may be performed on other decoders, such as decoders with a certain number of variable nodes, check nodes, and edges. One or more blocks of flowchart 300 may performed by decoder 132 executing machine-executable instructions in a non-transitory machine readable medium by a computer, hardware, a processor (e.g., a microprocessor), and/or machine. Flowchart 300 will be described in reference to a non-binary LDPC decoder with a Galois Field having a size q=64. In other embodiments, the non-binary LDPC decoder may use a Galois Field of any size, such as 4, 8, 16, 32, 64, 128, 256, etc.

At block 310, variable nodes 251-256 generate variable-node-to-check-node message vectors having q or complete set of vector components. In certain embodiments, the variable-node-to-check-node message vectors are in logarithm form, such as LDR vectors.

At block 320, check nodes 201-203 considers a subset k₁ of the components of the message vectors calculated by connected variable nodes at block 310. In certain embodiments, check nodes consider k₁ largest magnitude components of the message vectors generated at block 310. In certain embodiments, check nodes consider k₁ (out of q) largest magnitude LDR vector components or largest LDR values. For example, check nodes 201-203 may consider the sixteen (16) largest magnitude components out of the 64 components of the LDR vector message vectors calculated by variable nodes at block 310. Check nodes 201-203 considers the subset of the components of the variable-node-to-check-node message vectors to generate check-node-to-variable-node message update vectors.

At block 330, decoder 132 determines whether the values in the variable nodes 251-256 are converged or require adjustment based on update message vectors calculated at block 320. If the values have converged or the codeword is decoded (i.e., determine to be valid), decoding is ended for the codeword at block 370. If the values require adjustment and the iterations are below a set iteration limit, decoder proceeds back to block 310 for another iteration of generating message vectors based upon the check-node-to-variable-node message update vectors. Decoding of the codeword may proceed for any set limit. For example, if the iteration limit is set to one, then decoding progresses one iteration of considering k₁ components. If the iteration limit is set to more than one, then decoding progresses for one or more iterations of considering k₁ components until the codeword is decoded or until the iteration limit is reached. After a set number of iterations, if decoder 132 has still failed to decode or determine a valid codeword and iterations are at the iteration limit, then decoder 132 proceeds to block 340.

At block 340, variable nodes 251-256 generate variable-node-to-check-node message vectors having q or complete set of vector components. In certain embodiments, the variable-node-to-check-node message vectors are in logarithm form, such as LDR vectors. The message vectors are generated based upon the check-node-to-variable-node message update vectors.

At block 350, check nodes 201-203 considers a larger set k₂ (i.e., k₂>k₁) of the components of the message vectors than the subset at block 320. In certain embodiments, the check nodes consider the k₂ largest magnitude components of the message vectors generated at block 340. In certain embodiments, check nodes consider k₂ (out of q) largest magnitude LDR vector components or largest LDR values. In certain embodiments, the number of components considered k₂ is greater than k₁ but less than q of the Galois Field size of the non-binary LDPC codes. In other embodiments, the number of components considered k₂ may be all of the components q of the Galois Field size of the non-binary LDPC codes.

At block 360, decoder 132 determines whether the values in the variable nodes 251-256 are converged or require adjustment based on update message vectors calculated at block 350. If the values have converged or the codeword is decoded (i.e., determine to be valid), decoding is ended for the codeword at block 370. If the values require adjustment and the iterations are below a second set iteration limit, decoder proceeds back to block 340 for another additional iteration of generating message vectors based upon the check-node-to-variable-node message update vectors. For example, if the second iteration limit is set to one, then decoding progresses one iteration of considering k₂ components. If the second iteration limit is set to more than one, then decoding progresses for one or more iterations of considering k₂ components until the codeworded is decoded or until the second set iteration limit is reached. After a set number of iterations, if decoder 132 has still failed to decode or determine a valid codeword and iterations are at the second iteration limit, then decoder 132 proceeds to block 370 where decoding is halted.

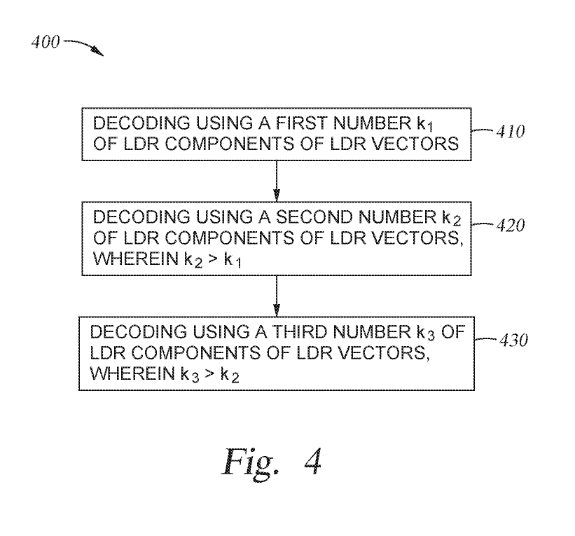

FIG. 4 is a flowchart 400 illustrating another embodiment of a process of decoding a codeword performed by a non-binary LDPC decoder. Flowchart 400 is described in reference to decoder 132 of FIG. 1 and FIG. 2. The process may be performed on other decoders, such as decoders with a certain number of variable nodes, check nodes, and edges. One or more blocks of flowchart 400 may performed by decoder 132 executing machine-executable instructions in a non-transitory machine readable medium by a computer, hardware, a processor (e.g., a microprocessor), and/or machine. Flowchart 400 will be described in reference to a non-binary LDPC decoder with a Galois Field having a size q=64. In other embodiments, the non-binary LDPC decoder may use a Galois Field of any size, such as 4, 8, 16, 32, 64, 128, 256, etc.

At block 410, decoder 132 performs a decoding process using a first number k₁ of LDR components of the LDR vectors for one set of one or more iterations. If decoder 132 does not decode the codeword after the set of iterations, then the decoding process proceeds to block 420.

At block 420, decoder 132 adjusts or adapts the decoding process to use a second number k₂ of LDR components of the LDR vectors, wherein the second number k₂ is greater than the first number k₁, for another set of one or more iterations. If decoder 132 does not decode the codeword after the another set of iterations, then the decoding process proceeds to block 430.

At block 430, decoder 132 further adjusts or adapts the decoding process to use a third number k₃ of LDR components of the LDR vectors, wherein the third number k₃ is greater than the second number k₂, for still another set of one or more iterations.

Flowchart 400 schematically illustrates that decoder 132 adaptively uses a certain number of LDR components of the LDR vectors. In certain embodiment, the number of LDR components are the largest magnitude LDR vector components or largest LDR values. Flowchart 400 schematically illustrates that decoder 132 adaptively uses a certain number of LDR components of the LDR vectors according to a certain number of iterations during decoding. For example, in one embodiment of the process of flowchart 400, at block 410, decoder 132 may use eight out of the sixty-four components of the LDR vectors for one or more iterations. If decoder 132 fails to decode the codeword (or fails to determine a valid codeword), then decoder 132 may adaptively increase the number of components to use, such as sixteen out of the sixty-four components of the LDR vectors, for an additional number of iterations at block 420. If decoder 132 still fails to decode the codeword, then decoder 132 may adaptively further increase the number of components to use, such as thirty-two out of the sixty-four components of the LDR vectors, for an additional number of iterations at block 430.

In another embodiment of the process of flowchart 400, at block 410, decoder 132 may consider 20% or less of the components of a Galois Field size q of the LDR vectors for one or more iterations. If decoder 132 fails to decode the codeword (or fails to determine a valid codeword), then decoder 132 may adaptively increase the number of components to consider, such as 50% or less of the components of a Galois Field size q of the LDR vectors for an additional number of iterations at block 420. If decoder 132 still fails to decode the codeword, then decoder 132 may adaptively further increase the number of components to use, such as all of the components of a Galois Field size q of the LDR vectors for an additional number of iterations at block 430.

Flowchart 300 of FIG. 3 and flowchart 400 of FIG. 4 illustrate various embodiments of a process of decoding a codeword performed by a non-binary LDPC decoder. Decoding may proceed by starting with a low complexity non-binary LDPC decoding and by increasing the complexity along the iterations of decoding. Non-binary LDPC decoding provides a lower error rate than binary LDPC decoding, but non-binary LDPC decoders have the drawback of increased time to perform one iteration of decoding due to the high complexity of decoding in comparison to binary LDPC decoders.

For non-binary LDPC decoding using min-sum calculations of all of the components over the Galois Field (q) of the LDR vector, the complexity of decoding is O(dq²) per edge connecting to a check node during update (where d is the degree of the check node). In embodiments of the present disclosure, non-binary LDPC decoding using min-sum calculations of a smaller number of components k of the LDR vector (where is k<q), the complexity of decoding is O(dk²) per edge. For example, for a LDR vector having a Galois Field (q) size of 64, the complexity of considering all of the LDR components is d64² while the complexity of decoding using a small number of components, such as if k=16, is d16². Therefore, complexity is greatly reduced. Decoding may progress by increasing the number of components k along the decoding process (i.e., after one or more iterations) until the codeword is decoded or until decoding is halted. The number of components k considered less than q may start at any number (such as low as one). The increase in the number of components k considered may be increased by any amount. The number of components k considered may be increased one time as shown in flowchart 300, may be increased two times as shown in flowchart 400, or may be increased any number of times. The iteration limits between increases may be set to any desired amount. The number of components k considered may be increased so that k stops at a certain number or may be increased all the way until all of the components of the LDR vector are considered (i.e, k=q).

In certain embodiments of the present disclosure, the number of components k of the LDR vector considered are the largest magnitude components or largest LDR values of the LDR vector. The largest magnitude components or largest LDR values of the LDR vector are used since the largest components/LDR values represent the highest probabilities or strongest beliefs that a variable node contains a certain symbol during that particular iteration. Therefore, the lowest probabilities or weakest beliefs are omitted in such iteration to speed completion of the iteration. In certain embodiments, the number of components k considered starts at 4 or more LDR components of a Galois Field (q) size of 64 or 5% or more of the Galois Field (q) vector components to help the initial decoding iterations start at sufficient complexity to help the values in the variable nodes converge or begin to converge.

Embodiments of the present disclosure may be used to advantage in error correction-code schemes in data storage devices, such as for NAND flash state devices. Embodiments of the present disclosure provide low error rate non-binary LDPC decoding with increased speed per iteration by starting with a low complexity decoding and increasing the complexity of the decoding after a certain number of iterations (i.e., as decoding progresses) if a codeword (or portion of a codeword) is not decoded or not validated.

In other embodiments of the present disclosure, non-binary LDPC decoding may progress by starting with high or full complexity and decreasing complexity as decoding progresses.

### EXAMPLES

The following are examples to illustrate various embodiments of a non-binary decoder operable to decode data storage in a data storage device. For illustration purposes, these examples will be described in reference to decoder 132 described in FIG. 1 and FIG. 2. Such examples are not meant to limit the scope of the disclosure unless specifically set forth in the claims.

### Example 1

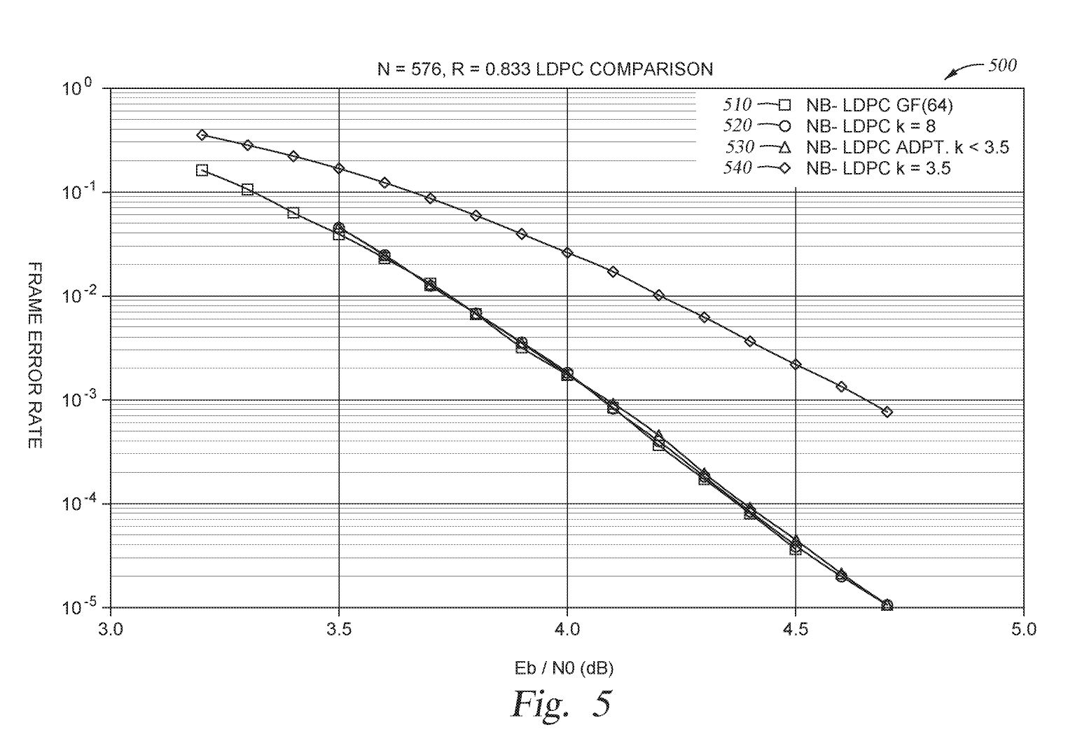

FIG. 5 is a graph 500 illustrating signal-to-noise ratios and frame error rates for simulation of one embodiment of decoder 132 performing non-binary LDPC decoding using LDR vectors having a Galois Field size of 64 in which N=576 bits, rate=0.833, and (dᵥd_{c)}=(2,12).

In graph 500, the x-axis shows the signal to noise ratio Eb/NO (dB) and the y-axis shows the frame error rate. Table 1 below provides a legend for relating the graph labels in graph 500 and the corresponding decoder implementations described herein.

TABLE 1

| Graph | |
|---|---|
| Label | Disclosure Implementation |
| 510 | non-binary LDPC decoding using 64 LDR components |
| 520 | non-binary LDPC decoding using 8 LDR components |
| 530 | iteration-adaptive non-binary LDPC decoding using an average |
| | of less than 3.5 LDR components |
| 540 | non-binary LDPC decoding using 3.5 LDR components |

Graph labels 510, 520, 540 represents non-binary LDPC decoding by considering a fix number of LDR components.

Graph label 530 represents non-binary LDPC decoding in which the number of LDR components considered adaptively changes over the iterations of decoding to consider a greater number of LDR components until the codeword (or portion thereof) is decoded or determined to be valid. For the example in graph label 530, non-binary LDPC decoding was simulated by first considering 3 largest LDR values out of the 64 components of LDR vectors for two or less iterations until the codeword is decoded. If the decoder has not decoded the codeword, then decoding proceeds by considering 4 largest LDR values out of the 64 components of LDR vectors for two or less additional iterations until the codeword is decoded. If the decoder has not decoded the codeword, then decoding proceeds by considering 8 largest LDR values out of the 64 components of LDR vectors until the codeword is decoded. The average of the LDR components of the LDR vector in the iteration-adaptive non-binary LDPC decoding considered at graph label 530 was less than 3.5 LDR components. The average k was calculated by summing the final k per codeword simulated divided by the total number of codewords simulated.

As shown in FIG. 5, the frame error rate of decoding at graph label 530 using iteration-adaptive non-binary decoding is similar to using a full complexity of 64 components of the Galois Field at graph label 510. The frame error rate of decoding at graph label 530 using iteration-adaptive non-binary decoding is also similar to using 8 out of 64 components of the Galois Field at graph label 520. Since the average of 3.5 components used in iteration-adaptive non-binary decoding at graph label 530 is less than the 8 components used in decoding at graph label 520, iteration-adaptive non-binary decoding proceeds faster per iteration will similar signal-to-noise ratio. The frame error rate of decoding at graph label 530 using iteration-adaptive non-binary decoding is much lower than the frame error rate of decoding at graph label 540 using a non-binary LDPC decoding considering a fixed number of 3.5 components in the simulation.

### Example 2

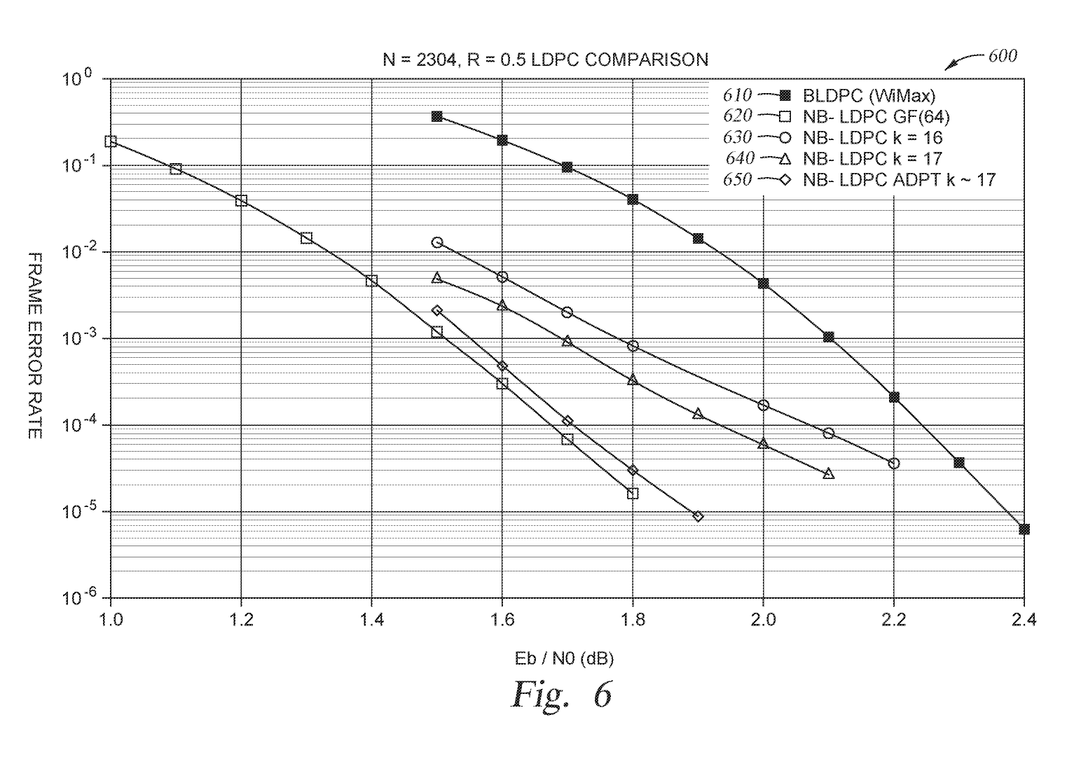

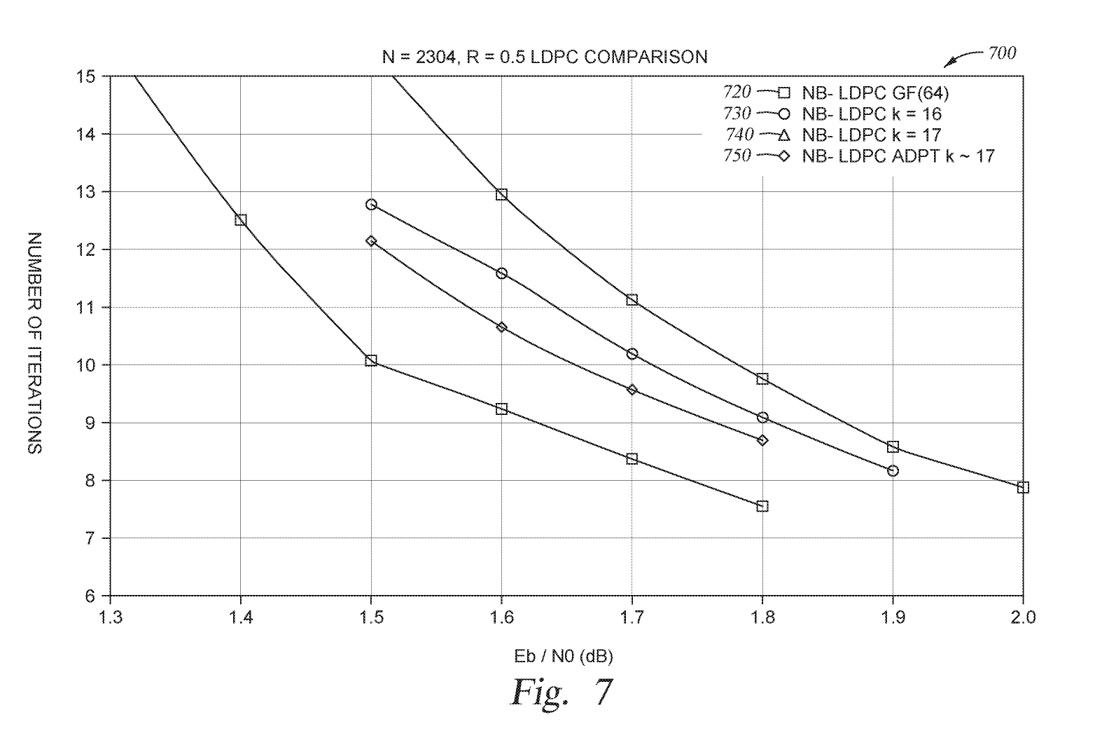

FIG. 6 is a graph 600 illustrating signal-to-noise ratios and frame error rates and FIG. 7 is a graph 700 illustration single-to-noise ratios and number of iterations for another embodiment of a decoder performing non-binary LDPC decoding. Graph 600 and graph 700 show simulation of decoders 132 performing non-binary LDPC decoding using LDR vectors having a Galois Field size of 64 in which N=2304 bits, rate=0.5, and (dv,dc)=(2,4).

In graph 600, the x-axis shows the signal to noise ratio Eb/N0 (dB) and the y-axis shows the frame error rate. Table 2 below provides a legend for relating the graph labels in graph 600 and the corresponding decoder implementations described herein.

TABLE 2

| Graph | |
|---|---|
| Label | Disclosure Implementation |
| 610 | binary LDPC decoding |
| 620 | non-binary LDPC decoding using 64 LDR components |
| 630 | non-binary LDPC decoding using 16 LDR components |
| 640 | non-binary LDPC decoding using 17 LDR components |
| 650 | iteration-adaptive non-binary LDPC decoding using an average |
| | of approximately 17 LDR components |

In graph 700, the x-axis shows the signal to noise ratio Eb/N0 (dB) and the y-axis shows the number of iterations to decode a codeword for a number of simulated decoders. Table 3 below provides a legend for relating the graph labels in graph 700 and the corresponding decoder implementations described herein.

TABLE 3

| Graph | |
|---|---|
| Label | Disclosure Implementation |
| 720 | non-binary LDPC decoding using 64 LDR components |
| 730 | non-binary LDPC decoding using 16 LDR components |
| 740 | non-binary LDPC decoding using 17 LDR components |
| 750 | iteration-adaptive non-binary LDPC decoding using an average |
| | of approximately 17 LDR components |

Graph labels 620, 630, 640 and graph labels 720, 730, 740 represent non-binary LDPC decoding by considering a fix number of LDR components.

Graph label 650 and graph label 750 represent non-binary LDPC decoding in which the number of LDR components considered adaptively changes over the iterations of decoding to consider a greater number of LDR components until the codeword (or portion thereof) is decoded or determined to be valid. For the example in graph label 650 and in graph label 750, non-binary LDPC decoding was simulated by first considering 16 largest LDR values out of the 64 components of LDR vectors for six or less iterations until the codeword is decoded. If the decoder has not decoded the codeword, then decoding proceeds by considering 20 largest LDR values out of the 64 components of LDR vectors for three or less additional iterations until the codeword is decoded. If the decoder has not decoded the codeword, then decoding proceeds by considering 24 largest LDR values out of the 64 components of LDR vectors until the codeword is decoded. The average of the LDR components of the LDR vector in the iteration-adaptive non-binary LDPC decoding considered at graph label 650 and at graph label 750 was approximately 17 LDR components. The average k was calculated by summing the final k per codeword simulated divided by the total number of codewords simulated.

As shown in FIG. 6, the frame error rate of decoding at graph label 650 using iteration-adaptive non-binary decoding has a slightly higher error rate than using a full complexity of 64 components of the Galois Field at graph label 620. The frame error rate of decoding at graph label 650 using iteration-adaptive non-binary decoding is lower than the frame error rate of decoding at graph label 630 using a non-binary LDPC decoding considering a fixed number of 16 components and at graph label 640 using a non-binary LDPC decoding considering a fixed number of 17 components in the simulation. The frame error rate for non-binary LDPC decoding at graph labels 620, 630, 640, 650 is much lower than the frame error for binary LDPC using WiMax codeword standards at graph label 610 in the simulation.

As shown in FIG. 7, the number of iterations to decode a codeword at graph label 750 using iteration-adaptive non-binary decoding is more than the number of iterations to decode a codeword than using a full complexity of 64 components of the Galois Field at graph label 720. The number of iterations to decode a codeword at graph label 750 using iteration-adaptive non-binary decoding is less than the number of iterations to decode a codeword than decoding at graph label 730 using a non-binary LDPC decoding considering a fixed number of 16 components and at graph label 740 using a non-binary LDPC decoding considering a fixed number of 17 components in the simulation.

What is claimed is:

1. A data storage device comprising:
a non-volatile memory;
a controller coupled to the non-volatile memory, the controller comprising a decoder; and
the decoder configured to decode a non-binary low-density parity-check (LDPC) codeword, the decoder operable to:
generate variable-node-to-check-node message vectors;
generate check-node-to-variable-node message vectors by considering a first number of components of the variable-node-to-check-node message vectors; and
generate check-node-to-variable-node message vectors by considering a second number of components of the variable-node-to-check-node message vectors, wherein the second number of components is greater than the first number of components.

2. The data storage device of claim 1, wherein the decoder is operable to generate check-node-to-variable-node message vectors by considering the second number of components after the decoder fails to determine a valid portion of the codeword after iterations of check-node-to-variable-node message vectors generated by considering the first number of components.

3. The data storage device of claim 1, wherein the second number of components of the variable-node-to-check-node message vectors is less than a Galois Field number of components of the variable-node-to-check-node message vectors.

4. The data storage device of claim 1, wherein the variable-node-to-check-node message vectors comprise log density ratio (LDR) vectors.

5. The data storage device of claim 4, wherein the first number of components considered comprise a first number of largest LDR values and wherein the second number of components considered comprise a second number of largest LDR values.

6. A method of decoding non-binary LDPC codes, comprising:
generating variable node message vectors in logarithm form;
generating check node message vectors in logarithm form at a first complexity less than a full complexity of considering all components of the variable node message vectors; and
generating check node message vectors in logarithm form at a second complexity greater than the first complexity.

7. The method of claim 6, wherein the first complexity comprises considering k₁ components and the full complexity comprises considering a Galois Field size of q, wherein k₁ is smaller in size than q.

8. The method of claim 7, wherein the second complexity comprises considering k₂ components, wherein k₁<k₂<q.

9. The method of claim 7, wherein the second complexity comprises considering k₂ components, wherein k₁<k₂=q.

10. The method of claim 6, wherein check node messages vectors are generated at the first complexity by considering a first number of largest magnitude components of the variable node message vectors and wherein check node messages vectors are generated at the second complexity by considering a second number of largest magnitude components of the variable node message vectors

11. A non-transitory computer readable storage medium containing instructions that, when executed by a controller, perform a method for decoding codewords in a data storage device, comprising:
determining a plurality of variable-node-to-check-node message vectors;
considering a first number of largest magnitude components of the variable-node-to-check-node message vectors for one or more first iterations; and
considering a second number of largest magnitude components of the variable-node-to-check-node message vectors for one or more second iterations, wherein the second number is larger in size than the first number.

12. The non-transitory computer readable storage medium of claim 11, wherein the message vectors are in logarithm form.

13. The non-transitory computer readable storage medium of claim 11, wherein the message vectors are log density ratio (LDR) vectors.

14. The non-transitory computer readable storage medium of claim 11, wherein the method further comprises a third number of components of the of the variable-node-to-check-node message vectors for one or more third iterations, wherein the third number is larger in size than the second number.

15. The non-transitory computer readable storage medium of claim 14, wherein the third number of components equals a full complexity of components of the variable-node-to-check-node message vectors.

16. A data storage device comprising:
a non-volatile memory; and
a controller coupled to the non-volatile memory, the controller comprising a decoder means;
the decoder means operable to decode a portion of a codeword by performing a non-binary low-density parity-check (LDPC) decoding process by:
using a first number of largest log density ratio (LDR) values; and
using a second number of largest LDR values, wherein the second number is greater in size than the first number.

17. The data storage device of claim 16, wherein precision of the non-binary LDPC decoding process is increased from using the first number to using the second number.

18. The data storage device of claim 16, wherein the second number of LDR values is used if using the first number of LDR values fails to decode the portion of the codeword after one or more iterations.

19. The data storage device of claim 18, wherein the non-binary LDPC decoding process further comprises using a third number of LDR values, wherein the third number is greater in size than the second number.

20. The data storage device of claim 19, wherein the third number of LDR values is used if using the second number of LDR values fails to decode the portion of the codeword after one or more additional iterations.
